(19) United States
(12) Patent Application Publication
(10) Pub. No.: US 2023/0335199 A1
(43) Pub. Date: Oct. 19, 2023

(54) IDENTIFYING A MOST RECENTLY PROGRAMMED PAGE DURING MEMORY DEVICE INITIALIZATION

(71) Applicant: Micron Technology, Inc., Boise, ID (US)

(72) Inventors: Jeremy BINFET, Boise, ID (US); Walter DI FRANCESCO, Avezzano (IT); Tommaso VALI, Sezze (IT); Jeffrey Scott MCNEIL, JR., Nampa, ID (US)

(21) Appl. No.: 17/659,755

(22) Filed: Apr. 19, 2022

(51) Int. Cl. G11C 16/22; G11C 16/04; G11C 16/26; G11C 16/34; G11C 16/10; G06F 12/14

(52) U.S. Cl. CPC G11C 16/22; G11C 16/0483; G11C 16/26; G11C 16/3445; G11C 16/10; G11C 16/3418; G06F 12/1458; G06F 2212/1052

(57) ABSTRACT

A memory device may be configured to perform an erase verify read operation to read from a plurality of access lines of a block of memory. The memory device may be configured to determine, based on performing the erase verify read operation, a quantity of access lines for which a corresponding page has been programmed, wherein each access line provides access to one or more pages of memory. The memory device may be configured to identify a most recently programmed page of the block of memory based on the determined quantity of access lines.

### TECHNICAL FIELD

The present disclosure generally relates to memory devices, methods performed by memory devices, and to identifying a most recently programmed page during memory device initialization.

### BACKGROUND

NAND flash memory, which may also be referred to as a “NAND” or a “NAND memory device,” is a non-volatile type of memory device that uses circuitry similar to or resembling NAND logic gates to enable electrically programming, erasing, and storing of data even when a power source is not supplied. NANDs may be used in various types of electronic devices, such as computers, mobile phones, or automobile computing systems, among other examples.

A NAND memory device may include an array of flash memory cells, a page buffer, and a column decoder. In addition, the NAND memory device may include a control logic unit (e.g., a controller), a row decoder, or an address buffer, among other examples. The memory cell array may include memory cell strings connected to bit lines, which are extended in a column direction.

A flash memory cell, which may be referred to as a “cell” or a “data cell,” of a NAND memory device may include a current path formed between a source and a drain on a semiconductor substrate. The flash memory cell may further include a floating gate and a control gate formed between insulating layers on the semiconductor substrate. A programming operation (sometimes called a write operation) of the flash memory cell is generally accomplished by grounding the source and the drain areas of the memory cell and the semiconductor substrate of a bulk area, and applying a high positive voltage, which may be referred to as a “program voltage,” a “programming power voltage,” or “VPP,” to a control gate to generate Fowler-Nordheim tunneling (referred to as “F-N tunneling”) between a floating gate and the semiconductor substrate. When F-N tunneling is occurring, electrons of the bulk area are accumulated on the floating gate by an electric field of VPP applied to the control gate to increase a threshold voltage of the memory cell.

An erasing operation of the flash memory cell is concurrently performed in units of sectors sharing the bulk area (referred to as “blocks”), by applying a high negative voltage, which may be referred to as an “erase voltage” or “Vera,” to the control gate and a configured voltage to the bulk area to generate the F-N tunneling. In this case, electrons accumulated on the floating gate are discharged into the source area, so that the flash memory cells have an erasing threshold voltage distribution.

Each memory cell string may have a plurality of floating gate type memory cells serially connected to each other. Access lines (sometimes called “word lines”) are extended in a row direction, and a control gate of each memory cell is connected to a corresponding access line. A memory device may include a plurality of page buffers connected between the bit lines and the column decoder. The column decoder is connected between the page buffer and data lines.

### BRIEF DESCRIPTION OF THE DRAWINGS

FIG. 1 is a diagram illustrating an example system capable of identifying a most recently programmed page during memory device initialization.

FIG. 2 is a diagram illustrating an example device capable of identifying a most recently programmed page during memory device initialization.

FIG. 3 is a diagram illustrating an example memory architecture that may be used by the device of FIG. 2.

FIGS. 4-8 are diagrams illustrating example operations associated with identifying a most recently programmed page during memory device initialization.

FIGS. 9-12 are flowcharts of example methods associated with cryptographic block locking.

FIG. 13 is a diagram illustrating an example environment that includes a memory device.

FIG. 14 is a diagram illustrating an example of components included in a memory device.

FIG. 15 is a diagram illustrating an example of a memory array.

### DETAILED DESCRIPTION

To improve security and protect sensitive or important data, a memory device may store security data that is used to perform security operations internally by the memory device, such as verifying a cryptographic signature and/or restricting access to data stored in memory. For example, the memory device may store security data that includes one or more parameters (e.g., a cryptographic key and/or a monotonic counter value), and the memory device may be configured to use those one or more parameters to generate a cryptographic signature. The memory device may compare the generated cryptographic signature with another cryptographic signature that is received in association with a command to read data from, write data to (sometimes referred to as “programming”), or erase data from the memory device. If the cryptographic signatures match, then the memory device may execute the command. Otherwise, the memory device may refrain from executing the command. As another example, the memory device may store security data that indicates one or more logical portions of the memory device (e.g., one or more memory blocks) to which access is restricted (e.g., read access, write access, and/or erase access).

Some non-volatile memory devices have a memory architecture that includes memory planes (sometimes called planes), memory blocks (sometimes called blocks), and memory pages (sometimes called pages). A plane may include multiple blocks, and a block may include multiple pages. In some non-volatile memory devices, such as NAND memory devices and NOR memory devices, when data is written or programmed to memory, the data is stored in an empty page of a block (e.g., a page to which data has not been written or programmed since a most recent erase operation was performed on the block). In some cases (e.g., for the security data), the data may be copied to volatile memory for ongoing use by the memory device (e.g., for verifying cryptographic signatures and/or enabling or disabling access to a block). However, when the memory device is powered off, the data stored in volatile memory is lost, and only the data stored in non-volatile memory is maintained.

As described above, a new version of security data (e.g., an update or modification to a stored version of the security data) is stored in a different page than a stored version, instead of overwriting the stored version and storing the new version in the same page in which the stored version is stored. As a result, when the memory device powers up, the memory device must locate the stored new version before the memory device can use the security data. In other words, the memory device must identify a page of security data that was most recently written or programmed. If the security data is always stored in a particular block of memory, then the memory device may identify the most recently programmed page of that block.

In some cases, the memory device may use a binary search algorithm to identify the most recently programmed page. However, performing a binary search is a resource-intensive and time-consuming task. Some devices and methods described herein enable a memory device to identify a most recently programmed page using fewer processing resources and less time than a binary search algorithm. For example, in a memory device that would take about 500 microseconds to identify a most recently programmed page using a binary search, that memory device may be capable of identifying the most recently programmed page in about 100 microseconds using the operations described herein. Furthermore, using the operations described herein, the memory device is capable of identifying the most recently programmed page using fewer memory operations (e.g., fewer read operations), which may conserve processing resources and reduce wear on the memory device.

Although some operations are described herein in connection with identifying a most recently programmed page that stores security data, these operations may be performed in connection with other types of data (e.g., user data that is not security data). Furthermore, although some operations are described herein in connection with identifying a most recently programmed page in a NAND memory device, these operations may be performed in connection with another type of memory device (e.g., a NOR memory device or another type of non-volatile memory device).

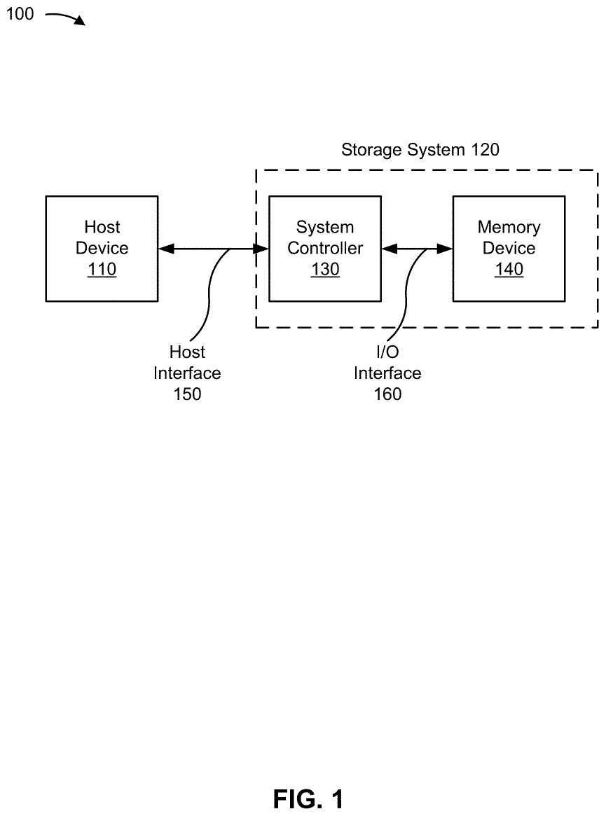

FIG. 1 is a diagram illustrating an example system 100 capable of identifying a most recently programmed page during memory device initialization. The system 100 may include one or more devices, apparatuses, and/or components for performing operations described herein (e.g., for identifying a most recently programmed page during memory device initialization). For example, the system 100 may include a host device 110 and a storage system 120. The storage system 120 may include a system controller 130 and a memory device 140. The host device 110 may communicate with the storage system 120 (e.g., the system controller 130 of the storage system 120) via a host interface 150. The system controller 130 and the memory device 140 may communicate via an input/output (I/O) interface 160.

The system 100 may be any electronic device configured to store data in memory. For example, the system 100 may be a computer, a mobile phone, a wired or wireless communication device, a network device, a server, and/or an Internet of Things (IoT) device. The host device 110 may include one or more processors configured to execute instructions and store data in the memory device 140. For example, the host device 110 may include a central processing unit (CPU), a graphics processing unit (GPU), a field-programmable gate array (FPGA), an application-specific integrated circuit (ASIC), and/or a controller.

The storage system 120 may be any electronic device configured to store data in memory. In some implementations, the storage system 120 may be an electronic device configured to store data persistently in non-volatile memory. For example, the storage system 120 may be a hard drive, a solid-state drive (SSD), a flash memory device (e.g., a NAND flash device), a universal serial bus (USB) thumb drive, a memory card (e.g., a secure digital (SD) card), a secondary storage device, and/or an embedded multimedia card (eMMC) device.

The system controller 130 may be any device configured to communicate with the host device (e.g., via the host interface 150) and the memory device 140 (e.g., via the I/O interface 160) and/or configured to control operations of the storage system 120. For example, the system controller 130 may include an ASIC, an FPGA, a processor, and/or a controller.

The memory device 140 may be a non-volatile memory device configured to maintain data stored in memory after the memory device 140 is powered off (e.g., configured for persistent data storage). In some implementations, the memory device 140 is a NAND memory device. Although some techniques are described herein in connection with NAND memory devices, in some implementations, one or more of these techniques may be performed in connection with other types of non-volatile memory devices, such as NOR memory devices.

The system controller 130 may transmit a command to the memory device 140 based on an instruction received from the host device 110. The command may be, for example, a read command, a write command (sometimes called a program command), or an erase command. Additionally, or alternatively, the command may indicate the data to be read, written, or erased, and/or may indicate a location (e.g., in memory) for the data to be read, written, or erased. In some implementations, the system controller 130 may transmit, to the memory device 140, a cryptographic signature associated with the command. The system controller 130 may generate the cryptographic signature based on, for example, the command (e.g., generated based on the instruction received from the host device 110), a cryptographic key (e.g., a private key or a secret key stored by the system controller 130), and/or a monotonic counter value. The cryptographic key may be stored by the system controller 130 and by the memory device 140 and may not be shared with other devices (e.g., other than the system controller 130 and the memory device 140). The monotonic counter value may be stored by the system controller 130 and by the memory device 140. In some implementations, the cryptographic signature may be generated (e.g., by the system controller 130) by applying a hash-based message authentication code (HMAC) function or algorithm to the command, the cryptographic key, and the monotonic counter value.

The memory device 140 may verify the cryptographic signature prior to executing the command. If the memory device 140 verifies the cryptographic signature (e.g., by generating a matching signature), then the memory device 140 may process and/or perform the command. If the memory device 140 fails to verify the cryptographic signature (e.g., by generating a corresponding signature that does not match the cryptographic signature), or if the memory device 140 does not receive a cryptographic signature in connection with a command that requires a cryptographic signature (e.g., a security command), then the memory device 140 may refrain from processing and/or performing the command. The terms “first cryptographic signature” and “second cryptographic signature” may be used herein to differentiate between the cryptographic signature generated by the system controller 130 (and transmitted from the system controller 130 to the memory device 140) and the cryptographic signature generated by the memory device 140 (to which the cryptographic signature received from the system controller 130 is compared).

For example, the memory device 140 may generate a corresponding signature based on the same inputs used by the system controller 130 to generate the cryptographic signature, such as the command (received from the system controller 130), the cryptographic key (stored by the memory device 140), and the monotonic counter value (e.g., stored by the memory device 140). Thus, the memory device 140 and the system controller 130 may separately store the cryptographic key and may separately store the monotonic counter value, which may be modified (e.g., incremented) after each command is received, processed, and/or performed. In this way, each command is associated with a unique cryptographic signature (e.g., different from other commands), thereby increasing security.

As indicated above, FIG. 1 is provided as an example. Other examples may differ from what is described with regard to FIG. 1.

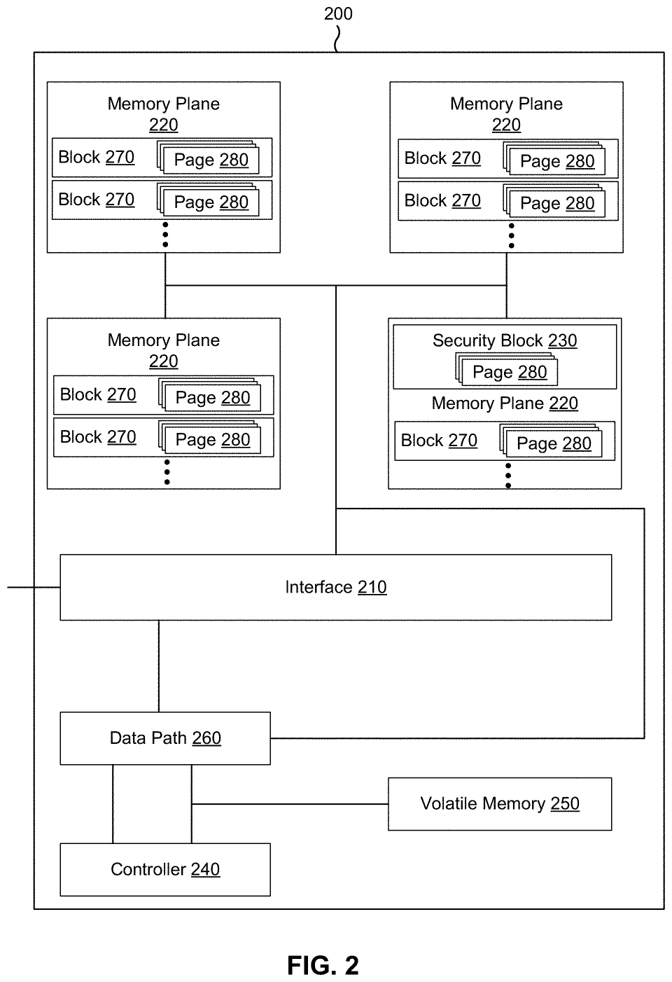

FIG. 2 is a diagram illustrating an example device 200 capable of identifying a most recently programmed page during memory device initialization. In some implementations, the device 200 is the memory device 140 described above in connection with FIG. 1. As shown, the device 200 may include an interface 210, one or more memory planes 220, a security block 230, a controller 240, a volatile memory 250, a data path 260, multiple blocks 270 (e.g., memory blocks), and/or multiple pages 280 (e.g., memory pages).

The interface 210 may include one or more components configured to receive data from a device external to the device 200 (e.g., the system controller 130) and transmit the data to a component internal to the device 200 (e.g., a memory plane 220, the controller 240, the volatile memory 250, and/or the data path 260), or vice versa. For example, the interface 210 may include physical components (e.g., bond pads, contact pads, wires, metallic components, and/or electrically conductive components) that connect with and/or interface with the system controller 130. Additionally, or alternatively, the interface 210 may include one or more components configured to receive data from a first component internal to the device 200 (e.g., a memory plane 220) and transmit the data to a second component internal to the device 200 (e.g., the controller 240, the volatile memory 250, and/or the data path 260), or vice versa. In some implementations, the interface 210 may be configured to convert from a first data rate and/or a first data format to a second data rate and/or a second data format. For example, the interface 210 may include one or more data buffers and/or one or more data registers for storing data to convert between different data rates or different data formats.

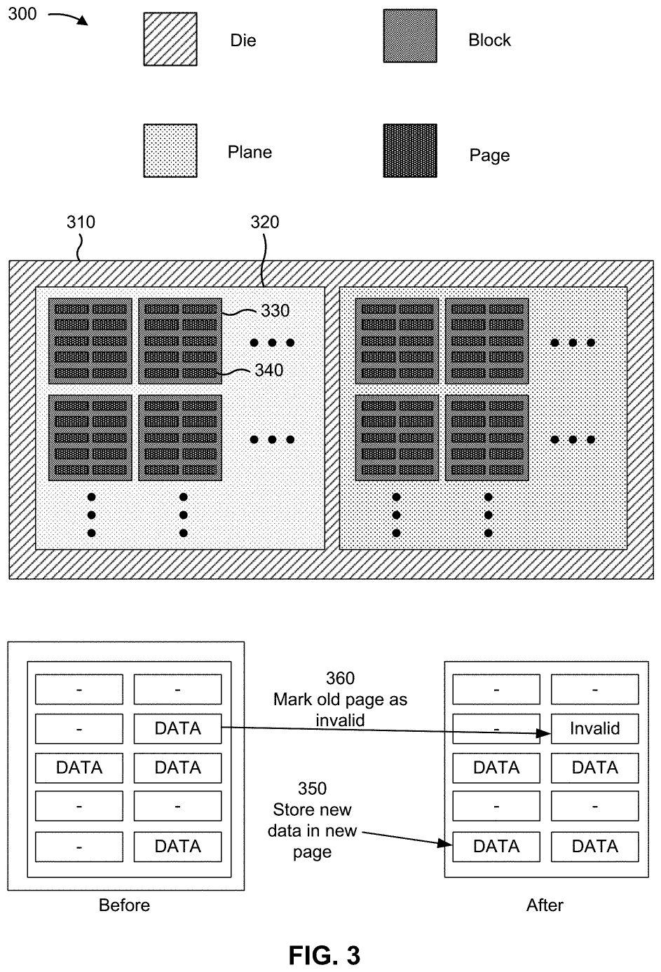

A memory plane 220 is a memory component described in more detail in connection with FIG. 3. A memory plane 220 may be disposed on a die and may include multiple memory blocks 270. A memory block 270 (sometimes called a “block”) is a memory component described in more detail in connection with FIG. 3. One of the blocks 270 (or more than one of the blocks) may be designated as a security block 230. The security block 230 may store security data. The security block 230 may be a reserved block or a dedicated block configured to store only the security data. For example, the security block 230 may be inaccessible to a host device, and the security block 230 may only be accessible by a controller 240 and/or other components internal to the device 200. In some implementations, a block address of the security block 230 may not exist in an address space accessible by the host device.

The security data may include, for example, a cryptographic key (e.g., used to generate a cryptographic signature as described above in connection with FIG. 1), a monotonic counter value (e.g., used to generate a cryptographic signature as described above in connection with FIG. 1), and/or a block lock record that indicates access restrictions for individual memory blocks 270 (e.g., a read restriction, a write restriction, and/or an erase restriction). In some implementations, the security data is used only internally by the device 200, and the security data is not accessible by a device external from the device 200. The security block 230 may include one or more pages 280, as described in more detail in connection with FIG. 3.

In some implementations, the device 200 may include multiple security blocks 230 (e.g., multiple blocks 270 that are designated as security blocks 230). In some implementations, the multiple security blocks 230 are included in the same memory plane 220 to reduce system complexity. As an example, the device 200 may include a first security block (e.g., a primary security block) and a second security block (e.g., a secondary security block or an alternate security block). Prior to erasing the first security block, the controller 240 may write the most recently stored security data of the first security block to the second security block. After erasing the first security block, the controller 240 may write the security data stored in the second security block back to the first security block. Alternatively, to reduce memory wear and improve wear-leveling, the controller 240 may continue writing data to the second security block until the second security block is full, and may then write the most recently stored security data of the second security block to the first security block prior to erasing the second security block, and so on. In some implementations, the controller 240 is configured to store information (e.g., in volatile memory and/or non-volatile memory) that identifies the security block 230 that is currently being used to store security data. The device 200 may perform operations described herein on that security block 230 to identify the most recently programmed page of that security block 230.

Although the device 200 is shown as including four memory planes 220, the device 200 may include a different quantity of memory planes 220. A block 270 is a memory component of a plane 220, and a page 280 is a memory component of a block 270. A block 270 may include multiple pages 280. Blocks 270 and pages 280 are described in more detail below in connection with FIG. 3.

The controller 240 may include one or more components configured to perform operations associated with identifying a most recently programmed page during memory device initialization. The controller 240 may include, for example, one or more processors, a microcontroller, an ASIC, and/or an FPGA. In some implementations, a non-transitory computer-readable medium (e.g., volatile memory and/or non-volatile memory) may store a set of instructions (e.g., one or more instructions or code) for execution by the controller 240. The controller 240 may execute the set of instructions to perform one or more operations or methods described herein. For example, the controller 240 may execute firmware instructions stored in a memory plane 220 (e.g., in a read-only memory block of the memory plane 220), which may be loaded into volatile memory 250 for execution by the controller 240. Additionally, or alternatively, the controller 240 may execute one or more instructions received from the system controller 130 and/or the host device 110. In some implementations, execution of the set of instructions, by the controller 240, causes the controller 240 and/or the device 200 to perform one or more operations or methods described herein. In some implementations, hardwired circuitry is used instead of or in combination with the instructions to perform one or more operations or methods described herein. Additionally, or alternatively, the controller 240 and/or one or more components of the device 200 may be configured to perform one or more operations or methods described herein. Thus, implementations described herein are not limited to any specific combination of hardware circuitry and software.

The volatile memory 250 may include one or more components configured to store data. The volatile memory 250 may store the data only when the volatile memory 250 is powered on and may lose the data when the volatile memory 250 is powered off. For example, the volatile memory 250 may be random-access memory (RAM), such as SRAM or DRAM.

The data path 260 may include one or more components configured to transfer data between components internal to the device 200. For example, the data path 260 may include one or more components configured to transfer data between the interface 210 and one or more other components internal to the device 200 (e.g., a memory plane 220, the controller 240, and/or the volatile memory 250). Additionally, or alternatively, the data path 260 may include one or more components configured to transfer data between the volatile memory 250 and a memory plane 220 (e.g., based on an instruction or command from the controller 240). In some implementations, the data path 260 may operate on the data to be transferred to convert the data from first data to second data.

The quantity and arrangement of components shown in FIG. 2 are provided as an example. In practice, the device 200 may include additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) of the device 200 may perform one or more functions described as being performed by another set of components of the device 200.

FIG. 3 is a diagram illustrating an example memory architecture 300 that may be used by the device 200. The device 200 may use the memory architecture 300 to store data. As shown, the memory architecture 300 may include a die 310, which may include multiple planes 320. A plane 320 may include multiple blocks 330. A block 330 may include multiple pages 340. Although FIG. 3 shows a particular quantity of planes 320 per die 310, a particular quantity of blocks 330 per plane 320, and a particular quantity of pages 340 per block 330, these quantities may be different than what is shown. In some implementations, the memory architecture 300 is a NAND memory architecture.

The die 310 is a structure made of semiconductor material, such as silicon. The device 200 may be fabricated on the die 310 (e.g., via a semiconductor device fabrication process). In some implementations, a die 310 is the smallest unit of memory that can independently execute commands. A memory chip or package may include one or more dies 310.

Each die 310 of a chip includes one or more planes 320. A plane 320 is sometimes called a memory plane. In some implementations, identical and concurrent operations can be performed on multiple planes 320 (sometimes with restrictions). Each plane 320 includes multiple blocks 330. A block 330 is sometimes called a memory block. Each block 330 includes multiple pages 340. A page 340 is sometimes called a memory page. A block 330 is the smallest unit of memory that can be erased. In other words, an individual page 340 of a block 330 cannot be erased without erasing every other page 340 of the block 330. A page 340 is the smallest unit of memory to which data can be written (i.e., the smallest unit of memory that can be programmed with data) and from which data can be read. The terminology “programming” memory and “writing to” memory may be used interchangeably. A page 340 may include multiple memory cells (sometimes called a string of memory cells) that are accessible via the same access line (sometimes called a word line).

In some implementations, read and write operations are performed for a specific page 340, while erase operations are performed for a block 330 (e.g., all pages 340 in the block 330). In some implementations, to prevent wearing out of memory, all pages 340 of a block 330 may be programmed before the block 330 is erased to enable a new program operation to be performed to a page 340 of the block 330. After a page 340 is programmed with data (called “old data” below), that data can be erased, but that data cannot be overwritten with new data prior to being erased. The erase operation would erase all pages 340 in the block 330, and erasing the entire block 330 every time that new data is to replace old data would quickly wear out the memory cells of the block 330. Thus, rather than performing an erase operation, the new data may be stored in a new page (e.g., an empty page), as shown by reference number 350, and the old page that stores the old data may be marked as invalid, as shown by reference number 360. The device 200 may then point operations associated with the data to the new page and may track invalid pages to prevent program operations from being performed on invalid pages prior to an erase operation. When the pages 340 of a block 330 are full (e.g., all or some threshold quantity of pages are either invalid or store valid data), the device 200 may copy the valid data (e.g., to a new block or to the same block after erasure) and may erase the block 330.

As indicated above, FIG. 3 is provided as an example. Other examples may differ from what is described with regard to FIG. 3.

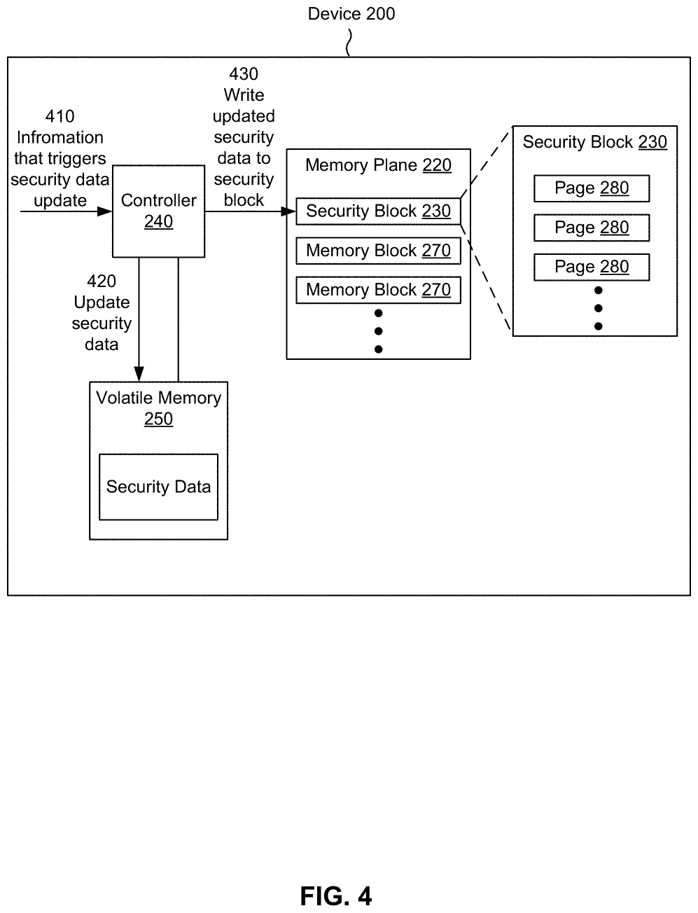

FIG. 4 is a diagram illustrating example operations associated with identifying a most recently programmed page during memory device initialization. The device 200 may perform or may be configured to perform one or more operations shown in FIG. 4 to write data to a page of memory. In some implementations, one or more operations of FIG. 4 described as being performed by the device 200 may be performed by the controller 240.

As shown by reference number 410, the device 200 may receive information that triggers an update to security data that is stored by the device 200 (sometimes called “triggering information”). In some implementations, the triggering information may be received from the host device 110 and/or the system controller 130. As an example, the triggering information may include an instruction to update the security data, such as an instruction to update a cryptographic key (e.g., a root key) stored in the security data (e.g., an instruction to store a new key or an instruction to replace an old key with a new key), an instruction to update a block lock record, and/or an instruction to update or store an indication of one or more access restrictions for one or more blocks 270.

As another example, the triggering information may include a command, such as a read command, a write command, or an erase command. In some implementations, the device 200 may update a monotonic counter value stored in the security data, such as by incrementing the monotonic counter value. For example, the device 200 may update the monotonic counter value after each command is received so that a different cryptographic signature is generated in association with each command, thereby increasing security. Thus, reception of a command may trigger updating of the security data and storing of a different monotonic counter value.

As shown by reference number 420, the device 200 may update the security data. For example, the device 200 may store updated security data (e.g., a new monotonic counter value, a new cryptographic key, and/or a new indication of an access restriction) based on the instruction and/or the command. As shown, the device 200 may store the updated security data in volatile memory 250.

As shown by reference number 430, the device 200 may write (or program) the updated security data to non-volatile memory, such as the security block 230. As described elsewhere herein, the security block 230 may be a block 270 that is reserved for storage of security data. The security block 230 may include multiple pages 280, and the device 200 may write the security data to a particular page 280 of the security block 230, such as an empty page (e.g., a page to which data has not been written or programmed since a most recent erase operation was performed on the security block 230). Additional details regarding programming or writing data to a page 280 are described above in connection with FIG. 3.

In some implementations, the device 200 may store the security data based on cryptographically verifying the triggering information that triggers the security data update (e.g., based on cryptographically verifying an instruction or command). For example, the device 200 may receive a cryptographic signature associated with the triggering information. If the device 200 verifies the cryptographic signature (e.g., by comparing the received cryptographic signature to another cryptographic signature generated by the device 200 using, for example, the triggering information, a cryptographic key, and a monotonic counter value), then the device 200 may store the updated security data. If the device 200 fails to verify the cryptographic signature, then the device 200 may refrain from storing the updated security data and may discard the triggering information. In some implementations, the device 200 may transmit a notification (e.g., to the system controller 130 and/or the host device 110) indicating that the triggering information could not be cryptographically verified.

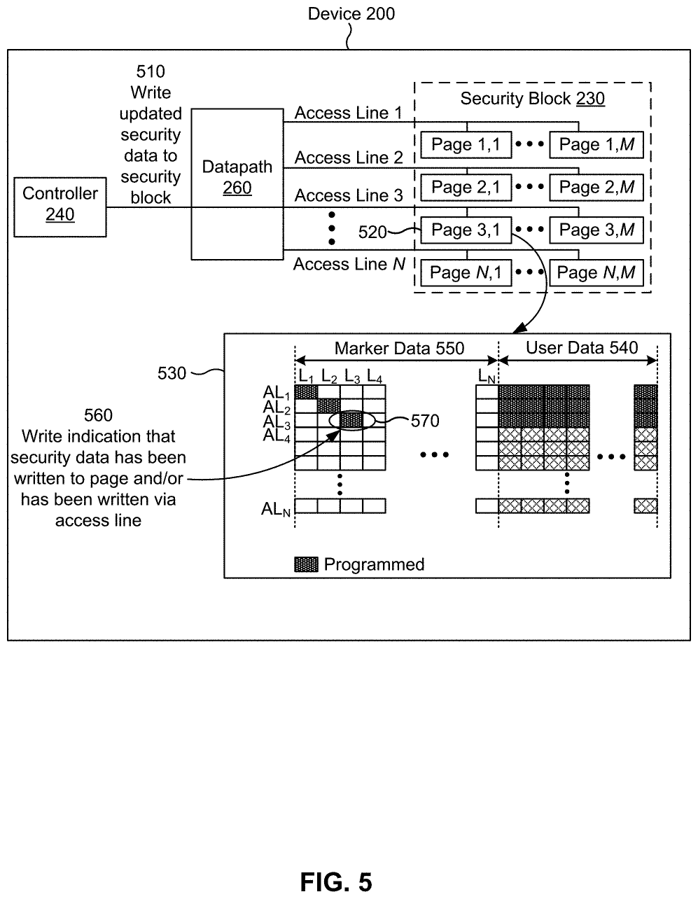

In some implementations, the device 200 may store the security data in the volatile memory 250, and the device 200 may then copy the security data to the security block 230 (e.g., via the data path 260), such as by writing security data, updated with new information, to a new page of the security block 230. Thus, the security data may be stored in both volatile memory 250 and non-volatile memory. The security data stored in volatile memory 250 may be used to perform one or more security operations associated with incoming commands while the device 200 is powered on. However, data stored in volatile memory 250 is lost when the device 200 is powered off. Thus, the security data may be stored in non-volatile memory (e.g., in the security block 230) for persistent storage. Upon powering up, the device 200 may need to locate the security data in non-volatile memory, such as by identifying a most recently programmed page of the security block 230. The device 200 may store the security data in non-volatile memory in a particular manner so as to reduce an amount of time and processing to identify the most recently programmed page and retrieve the security data from that page, as described in more detail below in connection with FIGS. 5-8.

As indicated above, FIG. 4 is provided as an example. Other examples may differ from what is described with regard to FIG. 4.

FIG. 5 is a diagram illustrating example operations associated with identifying a most recently programmed page during memory device initialization. The device 200 may perform or may be configured to perform one or more operations shown in FIG. 5 to write data to a page of memory such that the most recently programmed page can later be identified. In some implementations, one or more operations of FIG. 5 described as being performed by the device 200 may be performed by the controller 240.

As shown by reference number 510, the device 200 may write (or program) updated security data to non-volatile memory (e.g., a security block 230), as described above in connection with reference number 430 of FIG. 4. To write the security data to the non-volatile memory, the device 200 may identify an empty page of the security block 230 (e.g., based on information stored in a memory management table or other stored information that tracks page writes, empty pages, and/or non-empty pages). The device 200 may write the updated security data to the empty page. In some implementations, the device 200 may mark a page previously written with security data as invalid (e.g., by storing an indication that the previously written page is invalid). Additional details of writing data to pages are described above in connection with FIG. 3. In the example of FIG. 5, the device 200 writes the updated security data to an empty page 520 shown as “Page 3,1.”

As shown, the device 200 may write data to the empty page 520 via the data path 260. The data path 260 may connect the controller 240 with a set of access lines (sometimes called “word lines”), shown as Access Line 1, Access Line 2, Access Line 3, . . . , Access Line N. Each access line may provide access to one or more respective pages 280. In some implementations, each access line provides access to multiple pages 280. For example, Access Line 1 provides access to Page 1,1 through Page 1,M. Access Line 2 provides access to Page 2,1 through Page 2,M. Access Line 3 provides access to Page 3,1 through Page 3,M Access Line N provides access to Page N,1 through Page N,M. The nomenclature “Page i,j” indicates the j^{th} page accessible via access line i. In some implementations, the security block 230 may be divided into multiple sub-blocks, with each sub-block including a page (e.g., a single page). In this case, the nomenclature “Page i,j” indicates a page of sub-block j that is accessible via access line i.

As shown by reference number 530, a page of the security block 230 may be configured with a first memory portion 540 (sometimes called a “user data memory portion”) configured to store user data, and a second memory portion 550 (sometimes called a “marker data memory portion”) configured to store marker data. The user data may be data stored in memory based on the triggering information (e.g., an instruction or a command). For example, the user data may be the security data described elsewhere herein (e.g., a cryptographic key, a monotonic counter value, and/or an indication of an access restriction). Alternatively (e.g., in a scenario where the user data is not security data), the user data may be data that is received from the host device 110 to be written to memory or data that is read from memory to be provided to the host device 110.

The marker data may include an indication (sometimes called a “marker data indication”) of whether user data has been written to a page. For example, the marker data in the second memory portion 550 may indicate, for a page, whether user data has been written to the first memory portion 540 of that page (e.g., whether that page has been programmed with user data). In other words, the marker data may indicate whether a page is an empty page or a non-empty page. Alternatively, if multiple pages are accessible via a single access line, then the marker data may indicate, for an access line, whether at least one page, accessible via the access line, has been programmed (e.g., written to). In this case, the marker data may indicate whether an access line is associated with all empty pages or at least one non-empty page.

In some implementations, the second memory portion 550 may include a set of memory locations (e.g., one or more memory locations) associated with each access line of the security block 230. In other words, the second memory portion 550 may be configured to include a separate memory location (e.g., a separate set of one or more memory locations) for each access line via which the security block 230 is accessible. For example, the second memory portion 550 may include a first set of memory locations (shown as L₁) associated with a first access line (e.g., Access Line 1, also shown as AL₁) used to access pages of the security block 230, a second set of memory locations (shown as L₂) associated with a second access line (e.g., Access Line 2, also shown as AL₂) used to access pages of the security block 230, a third set of memory locations (shown as L₃) associated with a third access line (e.g., Access Line 3, also shown as AL₃) used to access pages of the security block 230, a fourth set of memory locations (shown as L₄) associated with a fourth access line (e.g., Access Line 4, shown as AL₄) used to access pages of the security block 230, and so on.

A value stored in a memory location may indicate whether at least one page of an access line corresponding to the memory location has been programmed. For example, a first value (e.g., 0) stored in memory location L₁ may indicate that none of the pages accessible via Access Line 1 (AL₁) have been programmed. A second value (e.g., 1) stored in memory location L₁ may indicate that at least one page accessible via Access Line 1 (AL₁) has been programmed. In other words, the first value (e.g., 0) stored in memory location L₁ may indicate that all of the pages accessible via Access Line 1 (AL₁) are empty, and the second value (e.g., 1) stored in memory location L₁ may indicate that at least one page accessible via Access Line 1 (AL₁) is not empty.

In some implementations, a single memory location (e.g., a single bit) in the second memory portion 550 may be associated with a single access line. In this case, the device 200 may set a value of the single bit (e.g., to the second value, such as 1) when a page of the corresponding access line is programmed. However, to reduce the likelihood of bit errors, in some implementations, multiple memory locations (e.g., multiple bits) in the second memory portion 550 may be associated with a single access line. In this case, the device 200 may set a value of each of the multiple bits (e.g., to the second value, such as 1) when a page of the corresponding access line is programmed. In some implementations, two bytes (16 bits) or three bytes (24 bits) may be associated with a single access line, and may each store an indication of whether a page of the access line has been programmed.

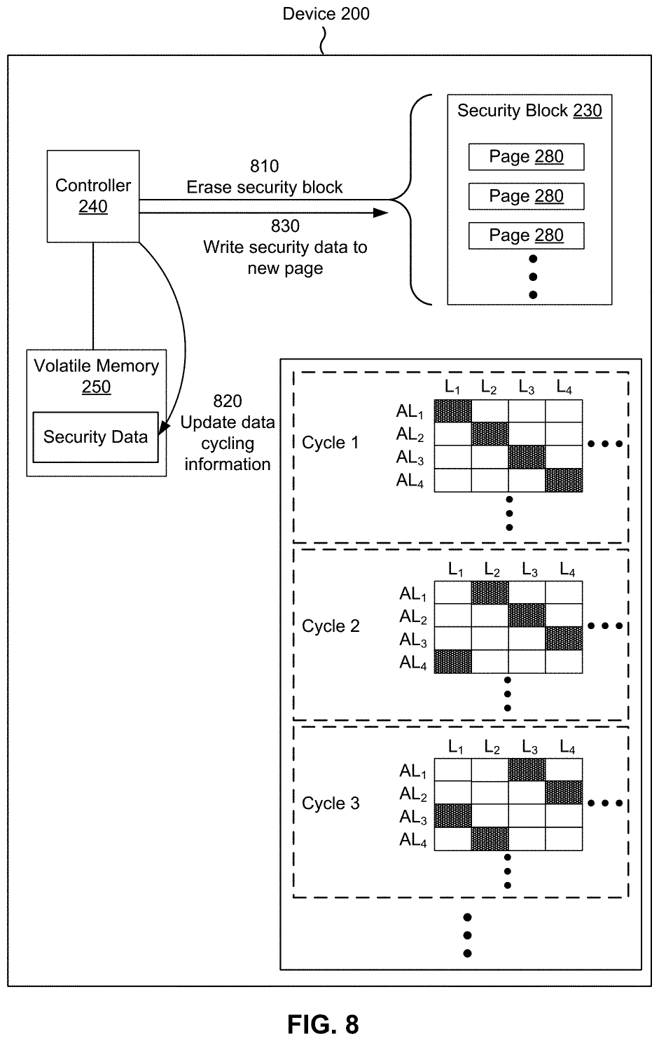

As shown by reference number 560, when the device 200 writes security data to a page of the security block 230 (e.g., Page 3,1), the device 200 may write the security data to the first memory portion 540 of the page, and may also write, in the second memory portion 550 of the page, an indication that data (e.g., user data, such as security data) has been written to the page. As shown, the device 200 may write the indication to a memory location 570 corresponding to the page (or corresponding to an access line via which the page is accessible). For example, prior to writing data to any pages associated with an access line, the memory location(s) associated with that access line may all store a first value (e.g., 0). When the device 200 writes to a page of that access line, then the device 200 may write a second value (e.g., 1) to all memory location(s) associated with that access line. Thus, the device 200 may identify a memory location in which to write the indication based on the page that has been programmed or is being programmed with user data and/or based on the access line used to access that page. In some implementations, the device 200 may store information that indicates correspondences (e.g., mappings) between access lines and memory locations of the second memory portion 550, as described in more detail below in connection with FIG. 8.

In the example of FIG. 5, the device 200 writes security data to an empty page 520 shown as “Page 3,1.” The empty page 520 is accessible via Access Line 3. Thus, after writing to the empty page 520 (such that the empty page 520 is no longer empty), the device 200 writes the second value to the memory location 570, which is memory location L₃ corresponding to AL₃. As described above, the memory location 570 may include a single bit or multiple bits (e.g., two or three bytes). The device 200 may write the second value (e.g., 1) to the single bit or the multiple bits to indicate that a page (e.g., page 520) accessible via the corresponding access line (Access Line 3) has been programmed.

In some implementations, each page of the security block 230 may include the same number of bits or bytes reserved for the marker data (e.g., the same number as every other page of the security block 230). For example, if the security block 230 is accessible via N access lines, as shown, then the second memory portion 550 may include N memory locations. In this case, each page of the security block 230 may include the N memory locations reserved for the marker data. The size of the second memory portion 550 may be equal to the number of memory locations (N) multiplied by the number of bits (or bytes) reserved for each memory location (e.g., the number of bits or bytes corresponding to an access line).

In the example of FIG. 5, the pages of the security block 230 are programmed with user data starting with Page 1,1 and proceeding with the other pages accessible via Access Line 1 (e.g., up to Page 1,M). After all pages accessible via Access Line 1 are programmed with user data, then the pages accessible via Access Line 2 are programmed with user data, starting with Page 2,1 and proceeding with the other pages accessible via Access Line 2 (e.g., up to Page 2,M), and so on. If the device 200 has programmed only pages accessible via the first access line (AL₁) with user data, then only the first memory location (L₁) may store an indication that a corresponding page (in this case, a page accessible via AL₁) has been programmed with user data. When the device 200 programs a page accessible via the second access line (AL₂) with user data, then the device 200 may copy (or write) the indication to the first memory location, and may also write an indication to the second memory location (L₂) to indicate that a corresponding page (e.g., a page accessible via AL₂) has been programmed with user data. Similarly, when the device 200 programs Page 3,1, the device 200 may copy (or write) the indication to the first memory location and the second memory location, and may also write an indication to the third memory location (L₃) to indicate that a corresponding page (e.g., a page accessible via AL₃) has been programmed with user data. In this way, the most recently programmed page may store an accurate record of the quantity of access lines that have been used to program a page of the security block 230 (in this case, three access lines) with user data.

In some implementations, a page 280 may be configured with the first memory portion 540 and the second memory portion 550 only if the page 280 is included in the security block 230 (or another particular type of block, such as a reserved block or a block having a particular block address). As a result, the device 200 may only write the marker data indication to the page if the page is included in the security block 230. Thus, in some implementations, the device 200 may determine whether a block to which user data is to be written is a security block 230. If the block is the security block 230, then the device 200 may write the marker data indication to the second memory portion 550 of a page to which user data is written. Otherwise, if the block is not the security block 230, then the device 200 may refrain from writing the marker data indication to the page to which user data is written. In this way, memory resources may be conserved (e.g., by reserving memory locations for the marker data only in the security block 230 and not in other blocks) and processing resources may be conserved (e.g., due to refraining from writing the marker data indication for non-security blocks).

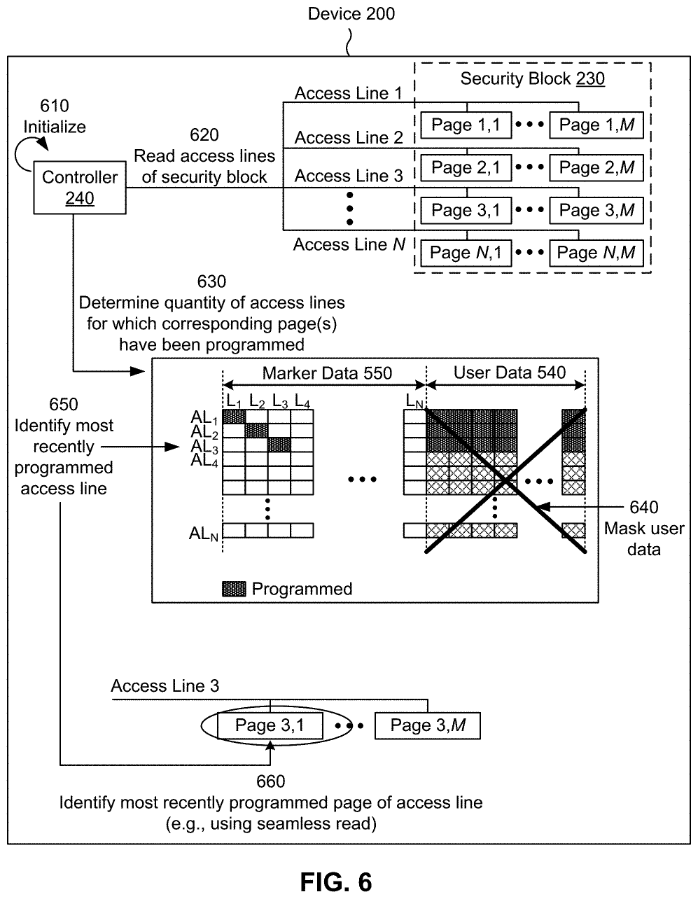

By writing the marker data indication to memory as described herein, the device 200 is enabled to identify a most recently programmed page using fewer processing resources, fewer memory operations, and/or less time than other techniques, such as a binary search algorithm. Details of identifying the most recently programmed page are described below in connection with FIG. 6.

As indicated above, FIG. 5 is provided as an example. Other examples may differ from what is described with regard to FIG. 5.

FIG. 6 is a diagram illustrating example operations associated with identifying a most recently programmed page during memory device initialization. The device 200 may perform or may be configured to perform one or more operations shown in FIG. 6 to identify a most recently programmed page. In some implementations, one or more operations of FIG. 6 described as being performed by the device 200 may be performed by the controller 240.

As shown by reference number 610, the device 200 may perform an initialization procedure, such as prior to reading or writing any user data to non-volatile memory. For example, the device 200 may perform the initialization procedure based on powering up and/or based on receiving an initialization command from the host device 110 and/or the system controller 130. During initialization, the device 200 may read a read-only memory (ROM) block and perform one or more initialization operations (or boot-up operations) based on data in the ROM block, such as a trim operation (e.g., based on a TRIM command) or a repair operation. As part of the initialization procedure, the device 200 may identify a most recently programmed page, such as a most recently programmed page of the security block 230. For example, the device 200 may identify the last page that was programmed prior to the device 200 powering down, sometimes called a “last valid page.”

As shown by reference number 620, to identify the most recently programmed page, the device 200 may read multiple access lines of the block 270 for which the most recently programmed page is being determined, such as the security block 230. For example, the device 200 may perform a read operation using all of the access lines that provide access (e.g., read access, write access, and/or erase access) to the security block 230. In some implementations, the device 200 may perform a read operation to read from all of those access lines. The read operation may be an operation associated with verifying that the security block 230 has been erased, sometimes called an “erase verify read operation” (which may be performed based on executing an erase verify command or an erase verify read command) or a “string read operation.” An erase verify read operation is typically performed after erasing a block of memory. As part of the erase verify read operation, all access line voltages are set to a read voltage to determine if there are any memory cells that are not in an erased state, indicating that the erase operation is not verified (e.g., to determine if any memory cells have a threshold voltage greater than the read voltage).

Thus, the device 200 may simultaneously or concurrently apply a read voltage to every access line of the security block 230 (e.g., every access line that provides access to the pages of the security block 230). Alternatively, the device 200 may simultaneously or concurrently apply a read voltage to multiple access lines of the security block 230, such as a first subset of access lines, followed by a second subset of access lines, such as when the device 200 performs multiple erase verify read operations, as described below. In some implementations, applying the read voltage to the multiple access lines of the security block 230 may include applying the read voltage to every access line of the security block 230 (e.g., using a single erase verify read operation or multiple erase verify read operations). In implementations described herein, the erase verify read operation may be performed to quickly (e.g., simultaneously or concurrently) read from every access line to assist with identifying a most recently programmed page, rather than to verify whether an erase operation was successful.

As shown by reference number 630, the device 200 may determine a quantity of access lines for which a corresponding page (e.g., at least one corresponding page) has been programmed (e.g., for which a corresponding page stores data, such as user data or security data). An access line for which a corresponding page has been programmed may be called a “programmed access line.” Here, a “corresponding page” refers to a page that is accessible via the access line (e.g., for read, write, and/or erase operations). The device 200 may determine the quantity of programmed access lines based on performing the read operation, which may be an erase verify read operation. An erase verify read operation may also be referred to as a string read operation, and may be used to determine if at least one memory cell across the access lines of the security block 230 (e.g., AL₁ through AL_{N}) is programmed for a memory location L. In some implementations, the erase verify read operation cannot be used to determine how many memory cells, accessible via an access line, are programmed. Rather, the erase verify read operation may be used to determine that at least one memory cell, accessible via an access line, has been programmed, without a determination of how many memory cells, accessible via the access line, have been programmed. However, by determining that at least one memory cell of a memory location L is programmed, the device 200 can determine a quantity of access lines, for which at least one memory cell has been programmed, based on the marker data program structure described elsewhere herein. For example, the device 200 may determine the quantity of programmed access line based on marker data (e.g., based on masking user data, as described below).

In a normal read operation (e.g., other than an erase verify read operation), the device 200 is configured to apply a pass voltage, greater than any memory cell threshold voltage on an access line, to all access lines except the target access line, and the device 200 is configured to apply a read voltage (e.g., less than the pass voltage) to the target access line (e.g., the access line to be accessed or read from). In an erase verify read operation, the device 200 is configured to apply a read voltage (e.g., less than the pass voltage) to all access lines in the security block 230 (or a subset or access lines if multiple erase verify read operations are performed, as described below). A threshold voltage may refer to the lowest voltage at which a memory cell can conduct current. A read voltage, sometimes called a read reference voltage, may be applied to an access line to be read from. The read voltage may be less than the pass voltage. A pass voltage, sometimes referred to as a pass-through voltage, may be equal to or greater than the maximum possible threshold voltage on all memory cells.

In some implementations, the device 200 may be configured to perform a read operation to read from all access lines of the security block 230 by performing a single erase verify read operation on all of those access lines. Alternatively, the device 200 may be configured to perform a read operation to read from all access lines of the security block 230 by performing multiple erase verify read operations, such a first erase verify read operation that applies the read voltage on all even access lines and that applies the pass voltage on all odd access lines, followed by a second erase verify read operation that applies the pass voltage on all even access lines and the read voltage on all odd access lines. Thus, the device 200 may be configured to perform a read operation to read from all access lines of the security block 230 by performing a single erase verify read operation on all access lines, by performing two erase verify read operations on two corresponding subsets of the access lines (e.g., a first erase verify read operation on a first subset of the access lines and a second erase verify read operation on a second subset of the access lines, where the first subset and second subset comprise all of the access lines), by performing three erase verify operations (e.g., on a corresponding three subsets of the access lines), or the like. This may be done to ensure conductivity across the entire string or memory location L.

As shown by reference number 640, to determine the quantity of programmed access lines, the device 200 may mask user data (e.g., security data) read via the access lines. As described above in connection with FIG. 5, each page in the security block 230 may be configured to include a first memory portion 540 configured to store user data (e.g., security data) and a second memory portion 550 configured to store marker data. The size of the first memory portion 540 may be the same across all of the pages, and the size of the second memory portion 550 may be the same across all of the pages. Furthermore, the first memory portion 540 may occupy the same set of logical byte positions across all pages. For example, a first user data memory portion may occupy bytes 0 through X for a first page of the security block 230, a second user data memory portion may occupy bytes 0 through X for a second page of the security block 230, and so on. Similarly, the second memory portion 550 may occupy the same set of logical byte positions across all pages. For example, a first marker data memory portion may occupy bytes X+1 through X+Y for a first page of the security block 230, a second marker data memory portion may occupy bytes X+1 through X+Y for a second page of the security block 230, and so on. The device 200 may mask the user data by ignoring, discarding, or refraining from reading the bytes occupied by the first memory portion 540 for each page. Thus, the device 200 may use only the marker data (and not the user data) to determine the quantity of programmed access lines.

In some implementations, the device 200 may determine the quantity of programmed pages by determining a quantity of memory locations in the marker data that have been programmed (where each memory location includes one or more bytes). In some implementations, the device may use a counter to determine the quantity of programmed access lines. The counter may be initialized with a value of zero prior to reading the access lines. When the access lines and marker data are read, if memory location L₁ has been programmed (e.g., with a value, such as 1, indicating that access line AL₁ is a programmed access line), then the device 200 may increment the counter. If memory location L₂ has been programmed (e.g., with a value, such as 1, indicating that access line AL₂ is a programmed access line), then the device 200 may again increment the counter. The device 200 may determine a stored value in each memory location of the second memory portion 550, may increment a counter value for each stored value (e.g., each value of 1) that indicates a programmed access line, and may refrain from incrementing the counter value for each stored value (e.g., each value of 0) that indicates an access line for which a corresponding page has not been programmed (e.g., that indicates a “non-programmed access line”). As described above in connection with FIG. 5, if a memory location includes multiple bits or multiple bytes, a single value (e.g., a single 0 or a single 1) may be determined for that memory location based on multiple bit values read from the memory location, such as by using error correction (e.g., a bit majority algorithm). For example, the device 200 may perform error correction to recover a value of the marker data indication. In the example of FIG. 6, the device 200 determines that three access lines have been programmed (e.g., AL₁, AL₂, and AL₃).

As shown by reference number 650, the device 200 may determine a most recently programmed access line of the security block 230. A “most recently programmed access line” may refer to an access line that provides access to a most recently programmed page of the security block 230. In some implementations, the device 200 may determine the most recently programmed access line based on the quantity of programmed access lines. For example, if the pages of the security block 230 are programmed in a particular order (e.g., after erasing the security block 230), then the access lines may be used to program the pages based on that order. For example, if AL₁ is used first in the order to program corresponding pages (e.g., Pages 1,1 through 1,M), AL₂ is used second in the order to program corresponding pages (e.g., Pages 2,1 through 2,M), and AL₃ is used third in the order to program corresponding pages (e.g., Pages 3,1 through 3,M), then the device 200 may determine that AL₃ is the most recently programmed access line based on determining that three access lines have been programmed. Thus, the device 200 may determine that an access line that is Z^{th} in the order is the most recently programmed access line, where Z equals the quantity of programmed access lines.

As shown by reference number 660, the device 200 may identify a most recently programmed page of the most recently programmed access line. For example, after identifying the access line that provides access to a most recently programmed page, the device 200 may determine which page, of multiple pages accessible via that access line, is the most recently programmed page. In some implementations, the device 200 may read (e.g., user data and/or marker data) from each page that is accessible via the access line to determine the most recently programmed page. For example, the pages of an access line may be programmed according to an order (e.g., initially Page 3,1, then Page 3,2, then Page 3,3, and so on for AL₃). In some implementations, the device 200 may read the pages in the order in which the pages are programmed. When the device 200 reads an empty page, then the device 200 may determine that a page (e.g., a non-empty page) that was read immediately prior to the empty page (e.g., with no intervening page reads) is the most recently programmed page. In the example of FIG. 5, the device 200 may read Page 3,1 and may determine that Page 3,1 is a non-empty page. The device 200 may then read Page 3,2 (not shown) and may determine that Page 3,2 is an empty page. In this case, the device 200 determines that Page 3,1, which is the page that was read immediately prior to reading the empty Page 3,2, is the most recently programmed page.

In some implementations, the device 200 may perform a seamless read operation to read all pages accessible via the most recently programmed access line. A “seamless read operation” may refer to a read operation (e.g., a single read operation) that is performed on a single access line across all pages of that access line. For example, the security block 230 may be divided into multiple sub-blocks. A sub-block may include multiple pages, with each page in the sub-block being accessible by a separate (e.g., respective) access line. Each single access line may provide access to a single page within each sub-block. For example, for a first sub-block, Access Line 1 provides access to Page 1,1, Access Line 2 provides Access to Page 2,1, Access Line 3 provides access to Page 3,1, Access Line N provides access to Page N,1 and so on. As another example, for an M^{th} sub-block, Access Line 1 provides access to Page 1,M, Access Line 2 provides Access to Page 2,M, Access Line 3 provides access to Page 3,M, Access Line N provides access to Page N,M, and so on. For the seamless read operation, all pages accessible via the most recently programmed access line may be read across all sub-blocks of the security block 230. Because the sub-blocks are filled according to an order (e.g., a logical order), the device 200 may identify the most recently programmed page as a last page that has been programmed according to the order.

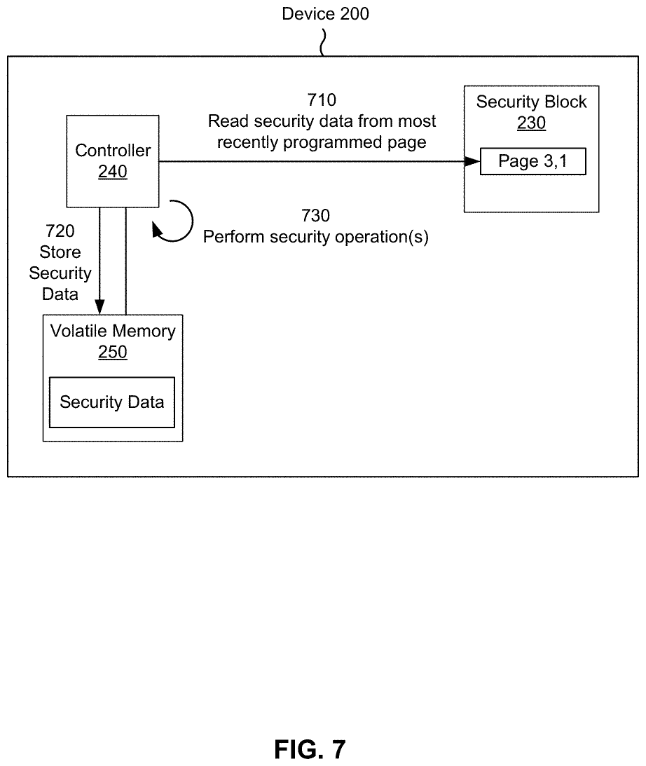

By using the marker data as described herein, the device 200 is enabled to identify a most recently programmed page using fewer processing resources, fewer memory operations, and/or less time than other techniques, such as a binary search algorithm. After identifying the most recently programmed page, the device 200 may read data from the most recently programmed page and may perform one or more operations based on that data, as described in more detail below in connection with FIG. 7.

As indicated above, FIG. 6 is provided as an example. Other examples may differ from what is described with regard to FIG. 6.

FIG. 7 is a diagram illustrating example operations associated with identifying a most recently programmed page during memory device initialization. The device 200 may perform or may be configured to perform one or more operations shown in FIG. 7 based on identifying a most recently programmed page. In some implementations, one or more operations of FIG. 7 described as being performed by the device 200 may be performed by the controller 240.

As shown by reference number 710, after identifying the most recently programmed page (e.g., as described above in connection with FIG. 6), the device 200 may read security data (or other user data) from the most recently programmed page. For example, the device 200 may read security data from the first memory portion 540 of the most recently programmed page. As described above, the security data may include, for example, a cryptographic key (e.g., used to generate a cryptographic signature), a monotonic counter value (e.g., used to generate a cryptographic signature), and/or a block lock record that indicates access restrictions for individual memory blocks (e.g., a read restriction, a write restriction, and/or an erase restriction).

As shown by reference number 720, the device 200 may store the security data, read from the most recently programmed page (e.g., read from non-volatile memory), in volatile memory 250. By copying the security data from non-volatile memory to volatile memory 250, the device 200 may be able to perform security operations more quickly using the security data stored in volatile memory 250 (rather than the security data stored in non-volatile memory).

As shown by reference number 730, the device 200 may perform one or more security operations using the security data (e.g., the security data stored in volatile memory 250). For example, the device 200 may use the security data (e.g., a cryptographic key and/or a monotonic counter value) to verify a cryptographic signature (e.g., to enable or disable access to a block and/or to enable or disable one or more operations), as described elsewhere herein. Additionally, or alternatively, the device 200 may use the security data (e.g., an access restriction) to restrict access to data stored in memory (e.g., user data stored in one or more blocks 270 other than the security block 230), as described elsewhere herein.

As indicated above, FIG. 7 is provided as an example. Other examples may differ from what is described with regard to FIG. 7.

FIG. 8 is a diagram illustrating example operations associated with identifying a most recently programmed page during memory device initialization. The device 200 may perform or may be configured to perform one or more operations shown in FIG. 8 to reduce wear on non-volatile memory due to operations described herein in connection with identifying a most recently programmed page. In some implementations, one or more operations of FIG. 8 described as being performed by the device 200 may be performed by the controller 240.

As shown by reference number 810, the device 200 may erase the security block 230. For example, the device 200 may erase all user data (e.g., security data) and marker data stored in all pages of the security block 230 during an erase operation. The device 200 may perform the erase operation after all of the pages (or a threshold quantity or percentage of pages) have been programmed and/or after the most recent security data has been written to an alternate security block (e.g., as described above in connection with FIG. 2). For example, when all or a threshold number or percentage of pages have been programmed and the device 200 has security data to write to a page, the device 200 may erase the security block 230 such that all pages are empty, and may write the security data to an empty page. Based on erasing the security block 230 (e.g., just prior to or just after erasing the security block 230), the device 200 may update data cycling information to reduce wear and/or extend the useful life of the device 200, as described below.

As shown by reference number 820, the device 200 may update data cycling information based on erasing the security block 230. The data cycling information may identify multiple data cycling patterns, and/or may identify a data cycling pattern to be used by the device 200 when writing marker data to the pages of the security block 230 (e.g., during a current program-erase cycle). A data cycling pattern may indicate correspondences between access lines and memory locations of the second memory portion 550. For example, a first data cycling pattern (shown as “Cycle 1”) indicates that a first access line (AL₁) is associated with a first memory location (L₁) in the second memory portion 550, indicates that a second access line (AL₂) is associated with a second memory location (L₂) in the second memory portion 550, indicates that a third access line (AL₃) is associated with a third memory location (L₃) in the second memory portion 550, and indicates that a fourth access line (AL₄) is associated with a fourth memory location (L₄) in the second memory portion 550. The device 200 may use the data cycling pattern to determine a memory location, in the second memory portion 550, to which marker data is to be written. For example, when the device 200 writes security data to a page via the first access line (AL₁), the device 200 may use the data cycling information (e.g., an indication of a currently active data cycling pattern) to determine that marker data for the first access line is to be written to the first memory location (L₁). Based on this determination, the device 200 may write the marker data to the first memory location based on writing security data to a page via the first access line.

As further shown in FIG. 8, a second data cycling pattern (shown as “Cycle 2”) indicates that the first access line (AL₁) is associated with the second memory location (L₂) in the second memory portion 550, indicates that the second access line (AL₂) is associated with the third memory location (L₃) in the second memory portion 550, indicates that the third access line (AL₃) is associated with the fourth memory location (L₄) in the second memory portion 550, and indicates that the fourth access line (AL₄) is associated with the first memory location (L₁) in the second memory portion 550. In this case, when the device 200 writes security data to a page via the first access line (AL₁), the device 200 may use the data cycling information (e.g., an indication of a currently active data cycling pattern) to determine that marker data for the first access line is to be written to the second memory location (L₂).

The device 200 may perform similar operations as those described above for other data cycling patterns, such as a third data cycling pattern (shown as “Cycle 3”) and/or one or more other data cycling patterns. Although the data cycling patterns shown in FIG. 8 and described herein use an example of four access lines and four corresponding memory locations, a different quantity of access lines and corresponding memory locations may be used.

The device 200 may store the data cycling information, such as the multiple data cycling patterns and an indication of an active data cycling pattern (e.g., an indication of which of the multiple data cycling patterns is to be used for writing marker data). In some implementations, the device 200 may store the data cycling information in non-volatile memory (e.g., in a page of the security block). In some implementations, the device 200 may copy the data cycling information to volatile memory 250 (e.g., when powered on). In some implementations, the device 200 may update the stored data cycling information to identify a different data cycling pattern (e.g., a different active data cycling pattern than one used for a preceding program-erase cycle) based on erasing the security block 230. When the device 200 updates the data cycling information, the device 200 may update the data cycling information in volatile memory 250 and/or in non-volatile memory.

In some implementations, the quantity of data cycling patterns identified in the data cycling information may be equal to the quantity of access lines via which the security block 230 can be accessed and/or may be equal to the quantity of memory locations in the second memory portion 550. For example, the data cycling information may include N possible data cycling patterns, where the value of Nis described above in connection with FIG. 5 (e.g., in connection with N access lines and N memory locations corresponding to those access lines). In some implementations, the device 200 may cycle through the data cycling patterns one at a time until all of the data cycling patterns have been used, and then may return to an initial data cycling pattern to repeat the cycle. In other words, the device 200 may use Cycle 1, then Cycle 2, then Cycle 3, and so on up to Cycle N. After using Cycle N, the device 200 may again use Cycle 1 and may repeat this cycle.

By cycling through different data cycling patterns, the device 200 levels out wear of memory locations (e.g., memory cells), rather than having some memory locations of the second memory portion 550 always being used for a corresponding access line and some memory locations of the second memory portion 550 never being used. This may reduce or level the wear on memory cells and may extend the life of the device 200 (e.g., the non-volatile memory of the device 200).

As indicated above, FIG. 8 is provided as an example. Other examples may differ from what is described with regard to FIG. 8.

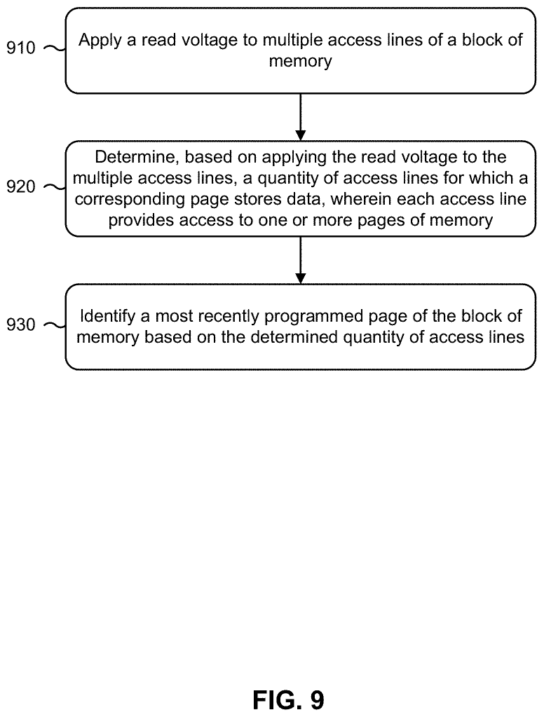

FIG. 9 is a flowchart of an example method 900 associated with identifying a most recently programmed page. In some implementations, a device (e.g., device 200) may perform or may be configured to perform one or more process blocks of FIG. 9. In some implementations, another device or a group of devices separate from or including the device 200 (e.g., memory device 140, controller 240) may perform or may be configured to perform one or more process blocks of FIG. 9. Additionally, or alternatively, one or more components of the device 200 (e.g., controller 240) may perform or may be configured to perform one or more process blocks of FIG. 9.

As shown in FIG. 9, the method 900 may include applying a read voltage to multiple access lines of a block of memory (block 910). As further shown in FIG. 9, the method 900 may include determining, based on applying the read voltage to the multiple access lines, a quantity of access lines for which a corresponding page stores data, wherein each access line provides access to one or more pages of memory (block 920). As further shown in FIG. 9, the method 900 may include identifying a most recently programmed page of the block of memory based on the determined quantity of access lines (block 930). In some implementations, applying the read voltage to the multiple access lines of the block of memory may include applying the read voltage to every access line of the block of memory (e.g., using a single erase verify read operation or multiple erase verify read operations).

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein, such as the operations described in connection with FIGS. 4-8.

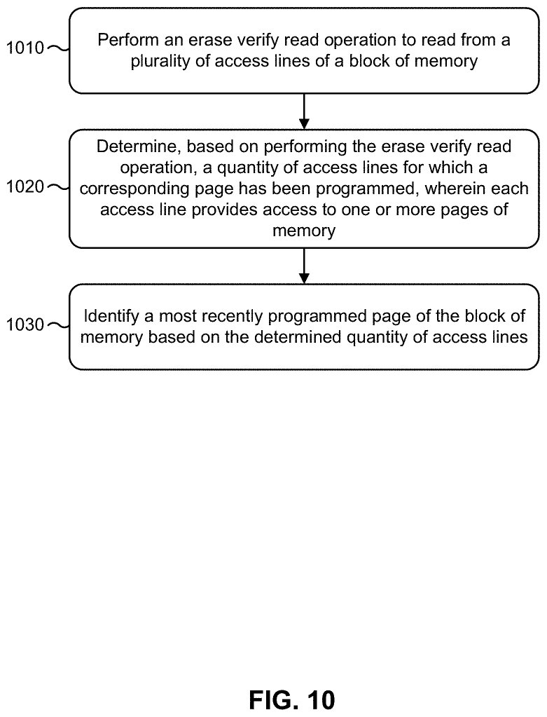

FIG. 10 is a flowchart of an example method 1000 associated with identifying a most recently programmed page. In some implementations, a device (e.g., device 200) may perform or may be configured to perform one or more process blocks of FIG. 10. In some implementations, another device or a group of devices separate from or including the device 200 (e.g., memory device 140, controller 240) may perform or may be configured to perform one or more process blocks of FIG. 10. Additionally, or alternatively, one or more components of the device 200 (e.g., controller 240) may perform or may be configured to perform one or more process blocks of FIG. 10.

As shown in FIG. 10, the method 1000 may include performing an erase verify read operation to read from a plurality of access lines of a block of memory (block 1010). As further shown in FIG. 10, the method 1000 may include determining, based on performing the erase verify read operation, a quantity of access lines for which a corresponding page has been programmed, wherein each access line provides access to one or more pages of memory (block 1020). As further shown in FIG. 10, the method 1000 may include identifying a most recently programmed page of the block of memory based on the determined quantity of access lines (block 1030).

Although FIG. 10 shows example blocks of a method 1000, in some implementations, the method 1000 may include additional blocks, fewer blocks, different blocks, or differently arranged blocks than those depicted in FIG. 10. Additionally, or alternatively, two or more of the blocks of the method 1000 may be performed in parallel. The method 1000 is an example of one method that may be performed by one or more devices described herein. These one or more devices may perform or may be configured to perform one or more other methods based on operations described herein, such as the operations described in connection with FIGS. 4-8.

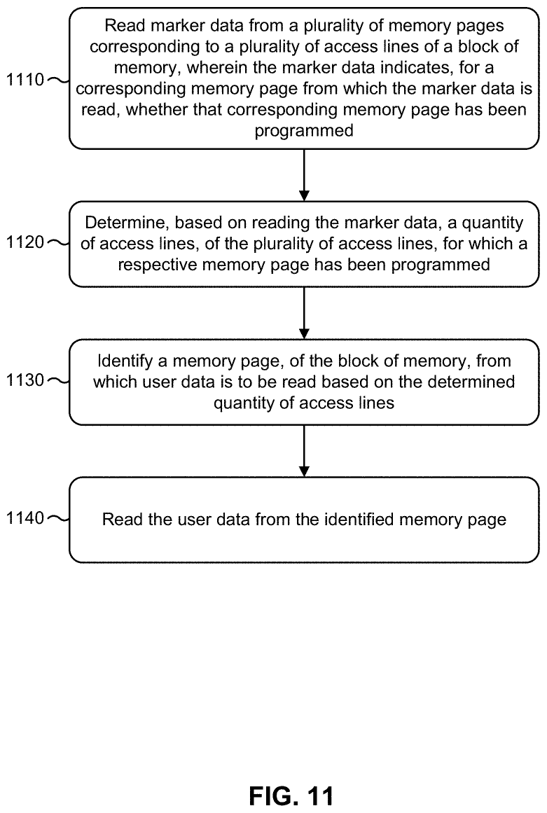

FIG. 11 is a flowchart of an example method 1100 associated with identifying a most recently programmed page. In some implementations, a device (e.g., device 200) may perform or may be configured to perform one or more process blocks of FIG. 11. In some implementations, another device or a group of devices separate from or including the device 200 (e.g., memory device 140, controller 240) may perform or may be configured to perform one or more process blocks of FIG. 11. Additionally, or alternatively, one or more components of the device 200 (e.g., controller 240) may perform or may be configured to perform one or more process blocks of FIG. 11.

As shown in FIG. 11, the method 1100 may include reading marker data from a plurality of memory pages corresponding to a plurality of access lines of a block of memory, wherein the marker data indicates, for a corresponding memory page from which the marker data is read, whether that corresponding memory page has been programmed (block 1110). As further shown in FIG. 11, the method 1100 may include determining, based on reading the marker data, a quantity of access lines, of the plurality of access lines, for which a respective memory page has been programmed (block 1120). As further shown in FIG. 11, the method 1100 may include identifying a memory page, of the block of memory, from which user data is to be read based on the determined quantity of access lines (block 1130). As further shown in FIG. 11, the method 1100 may include reading the user data from the identified memory page (block 1140).

Although FIG. 11 shows example blocks of a method 1100, in some implementations, the method 1100 may include additional blocks, fewer blocks, different blocks, or differently arranged blocks than those depicted in FIG. 11. Additionally, or alternatively, two or more of the blocks of the method 1100 may be performed in parallel. The method 1100 is an example of one method that may be performed by one or more devices described herein. These one or more devices may perform or may be configured to perform one or more other methods based on operations described herein, such as the operations described in connection with FIGS. 4-8.

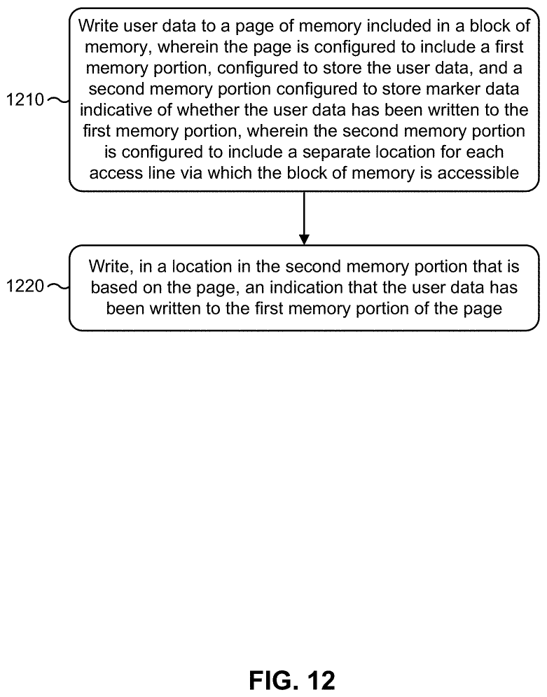

FIG. 12 is a flowchart of an example method 1200 associated with identifying a most recently programmed page. In some implementations, a device (e.g., device 200) may perform or may be configured to perform one or more process blocks of FIG. 12. In some implementations, another device or a group of devices separate from or including the device 200 (e.g., memory device 140, controller 240) may perform or may be configured to perform one or more process blocks of FIG. 12. Additionally, or alternatively, one or more components of the device 200 (e.g., controller 240) may perform or may be configured to perform one or more process blocks of FIG. 12.

As shown in FIG. 12, the method 1200 may include writing user data to a page of memory included in a block of memory, wherein the page is configured to include a first memory portion configured to store the user data and a second memory portion configured to store marker data indicative of whether the user data has been written to the first memory portion, wherein the second memory portion is configured to include a separate location for each access line via which the block of memory is accessible (block 1210). As further shown in FIG. 12, the method 1200 may include writing, in a location in the second memory portion that is based on the page, an indication that the user data has been written to the first memory portion of the page (block 1220).

Although FIG. 12 shows example blocks of a method 1200, in some implementations, the method 1200 may include additional blocks, fewer blocks, different blocks, or differently arranged blocks than those depicted in FIG. 12. Additionally, or alternatively, two or more of the blocks of the method 1200 may be performed in parallel. The method 1200 is an example of one method that may be performed by one or more devices described herein. These one or more devices may perform or may be configured to perform one or more other methods based on operations described herein, such as the operations described in connection with FIGS. 4-8.

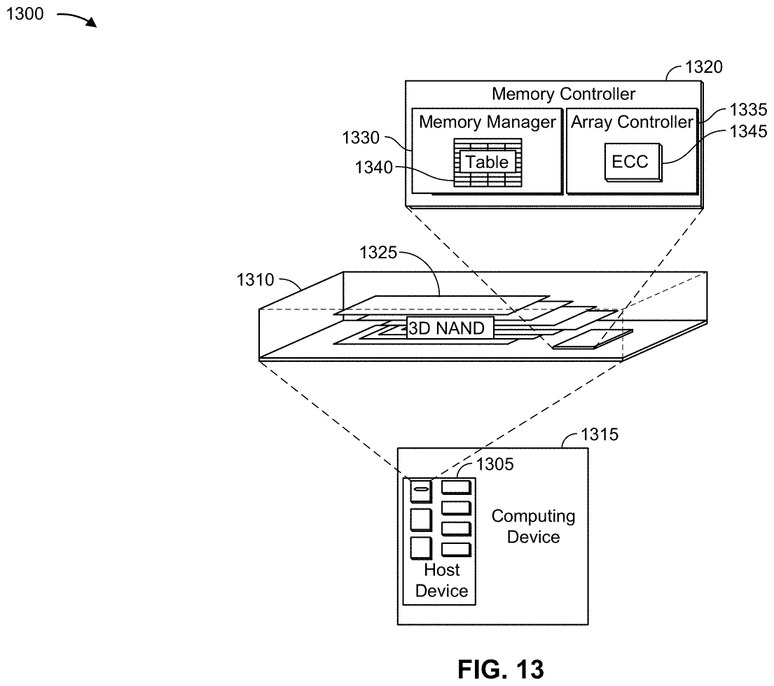

FIG. 13 is a diagram illustrating an example environment 1300 that includes a memory device. As shown in FIG. 13, the environment 1300 includes a host device 1305 and a memory device 1310 configured to communicate via a communication interface. The host device 1305 and/or the memory device 1310 may be included in a computing device 1315, such as a computer, a server, and/or an IoT device. For example, the memory device 1310 may be a discrete memory component of the host device 1305. Alternatively, the memory device 1310 may be a portion of an integrated circuit that is included with one or more other components of the host device 1305. In some implementations, the host device 1305 may be the host device 110, and/or the memory device 1310 may be the memory device 140 and/or the device 200.

The memory device 1310 may include a memory controller 1320, which may be the controller 240. Additionally, or alternatively, the memory device 1310 may include a memory array 1325. The memory array 1325 may include one or more memory dies. The memory array 1325 is shown as a three-dimensional (3D) NAND array. In 3D array semiconductor memory technology, memory structures are stacked vertically, which increases the quantity of memory cells that can fit in a given die size. Although the memory array 1325 is shown as a 3D array, in some implementations, the memory array 1325 is a two-dimensional (2D) array.

The host device 1305 and/or the memory device 1310 may include one or more communication interfaces configured to transfer data between the memory device 1310 and one or more components of the host device 1305. For example, the host device 1305 and/or the memory device 1310 may include a Serial Advanced Technology Attachment (SATA) interface, a Peripheral Component Interconnect Express (PCIe) interface, a USB interface, a Universal Flash Storage (UFS) interface, and/or an embedded multimedia card (eMMC) interface.

The memory controller 1320 may include, for example, one or more processors, a microcontroller, an ASIC, and/or an FPGA. In some implementations, a non-transitory computer-readable medium (e.g., volatile memory and/or non-volatile memory) may store a set of instructions (e.g., one or more instructions or code) for execution by the memory controller 1320. The memory controller 1320 may execute the set of instructions to perform one or more operations or methods described herein. In some implementations, execution of the set of instructions, by the memory controller 1320, causes the memory controller 1320 and/or the memory device 1310 to perform one or more operations or methods described herein. In some implementations, hardwired circuitry is used instead of or in combination with the instructions to perform one or more operations or methods described herein. Additionally, or alternatively, the memory controller 1320 and/or one or more components of the memory device 1310 may be configured to perform one or more operations or methods described herein.

The memory controller 1320 may receive one or more instructions from the host device 1305 and may communicate with the memory array based on the one or more instructions, such as to transfer data to (e.g., write or program), to transfer data from (e.g., read), and/or to erase a portion of the memory array 1325 (e.g., one or more memory cells, pages, sub-blocks, blocks, or planes of the memory array 1325). Additionally, or alternatively, the memory controller 1320 may include one or more components configured to control access to the memory array 1325 and/or to provide a translation layer between the host device 1305 and the memory device 1310 for access to the memory array 1325. The memory controller 1320 may include one or more input/output (I/O) circuits, lines, or interfaces to transfer data to or from the memory array 1325. In some implementations, the memory controller 1320 may include a memory manager 1330 and/or an array controller 1335.

The memory manager 1330 may include one or more components (e.g., circuitry) configured to perform one or more memory management functions, such as wear leveling, error detection, error correction, block retirement, or one or more other memory management functions. The memory manager 1330 may parse or format a host command (e.g., a command received from the host device 1305) into a memory command (e.g., a command for performing an operation on the memory array 1325). Additionally, or alternatively, the memory manager 1330 may generate one or more memory commands based on one or more instructions received from the array controller 1335 and/or one or more other components of the memory device 1310.

The memory manager 1330 may include or may operate using one or more memory management tables 1340 configured to store information associated with the memory array 1325. For example, a memory management table 1340 may include information regarding block age, block erase count, error history, or one or more error counts associated with one or more blocks of memory cells included in the memory array 1325.

The array controller 1335 may include one or more components (e.g., circuitry) configured to control one or more memory operations associated with writing data to, reading data from, or erasing one or more memory cells of the memory array 1325. The one or more memory operations may be based on, for example, a host command received from the host device 1305 or a command generated internally by the memory device 1310 (e.g., in association with wear leveling, error detection, and/or error correction). In some implementations, the array controller 1335 may include an error correction code (ECC) component 1345. The ECC component 1345 may include one or more components configured to detect or correct errors associated with writing data to or reading data from one or more memory cells of the memory array 1325.

One or more devices or components shown in FIG. 13 may be used to carry out operations described elsewhere herein, such as one or more operations of FIGS. 4-8 and/or one or more process blocks of the methods of FIGS. 9-12.

As indicated above, FIG. 13 is provided as an example. Other examples may differ from what is described with regard to FIG. 13.

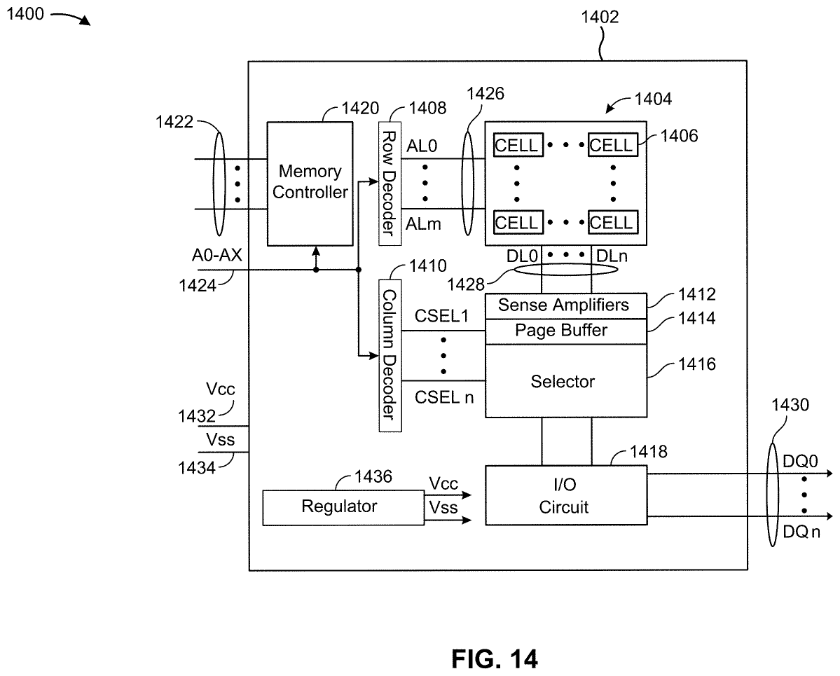

FIG. 14 is a diagram illustrating an example 1400 of components included in a memory device 1402. The memory device 1402 may be the memory device 1310, the memory device 140, and/or the device 200. The memory device 1402 may include a memory array 1404 having multiple memory cells 1406. The memory device 1402 may include one or more components (e.g., circuits) to transmit signals to or perform memory operations on the memory array 1404. For example, the memory device 1402 may include a row decoder 1408, a column decoder 1410, one or more sense amplifiers 1412, a page buffer 1414, a selector 1416, an input/output (I/O) circuit 1418, and a memory controller 1420. The memory controller 1420 may be the memory controller 1320 and/or the controller 240.

The memory controller 1420 may control memory operations of the memory device 1402 according to one or more signals received via one or more control lines 1422, such as one or more clock signals or control signals that indicate an operation (e.g., write, read, or erase) to be performed. Additionally, or alternatively, the memory controller 1420 may determine one or memory cells 1406 upon which the operation is to be performed based on one or more signals received via one or more address lines 1424, such as one or more address signals (shown as AO-AX). A host device external from the memory device 1402 may control the values of the control signals on the control lines 1422 and/or the address signals on the address line 1424.

The memory device 1402 may use access lines 1426 (sometimes called word lines or row lines, and shown as AL0-ALm) and data lines 1428 (sometimes called digit lines, bit lines, or column lines, and shown as DL0-DLn) to transfer data to or from one or more of the memory cells 1406. For example, the row decoder 1408 and the column decoder 1410 may receive and decode the address signals (AO-AX) from the address line 1424 and may determine which of the memory cells 1406 are to be accessed based on the address signals. The row decoder 1408 and the column decoder 1410 may provide signals to those memory cells 1406 via one or more access lines 1426 and one or more data lines 1428, respectively.

For example, the column decoder 1410 may receive and decode address signals into one or more column select signals (shown as CSEL1-CSELn). The selector 1416 may receive the column select signals and may select data in the page buffer 1414 that represents values of data to be read from or to be programmed into memory cells 1406. The page buffer 1414 may be configured to store data received from a host device before the data is programmed into relevant portions of the memory array 1404, or the page buffer 1414 may store data read from the memory array 1404 before the data is transmitted to the host device. The sense amplifiers 1412 may be configured to determine the values to be read from or written to the memory cells 1406 using the data lines 1428. For example, in a selected string of memory cells 1406, a sense amplifier 1412 may read a logic level in a memory cell 1406 in response to a read current flowing through the selected string to a data line 1428. The I/O circuit 1418 may transfer values of data into or out of the memory device 1402 (e.g., to or from a host device), such as into or out of the page buffer 1414 or the memory array 1404, using I/O lines 1430 (shown as (DQ0-DQn)).

The memory controller 1420 may receive positive and negative supply signals, such as a supply voltage (Vcc) 1432 and a negative supply (Vss) 1434 (e.g., a ground potential), from an external source or power supply (e.g., an internal battery, an external battery, and/or an AC-to-DC converter). In some implementations, the memory controller 1420 may include a regulator 1436 to internally provide positive or negative supply signals.

One or more devices or components shown in FIG. 14 may be used to carry out operations described elsewhere herein, such as one or more operations of FIGS. 4-8 and/or one or more process blocks of the methods of FIGS. 9-12.

As indicated above, FIG. 14 is provided as an example. Other examples may differ from what is described with regard to FIG. 14.

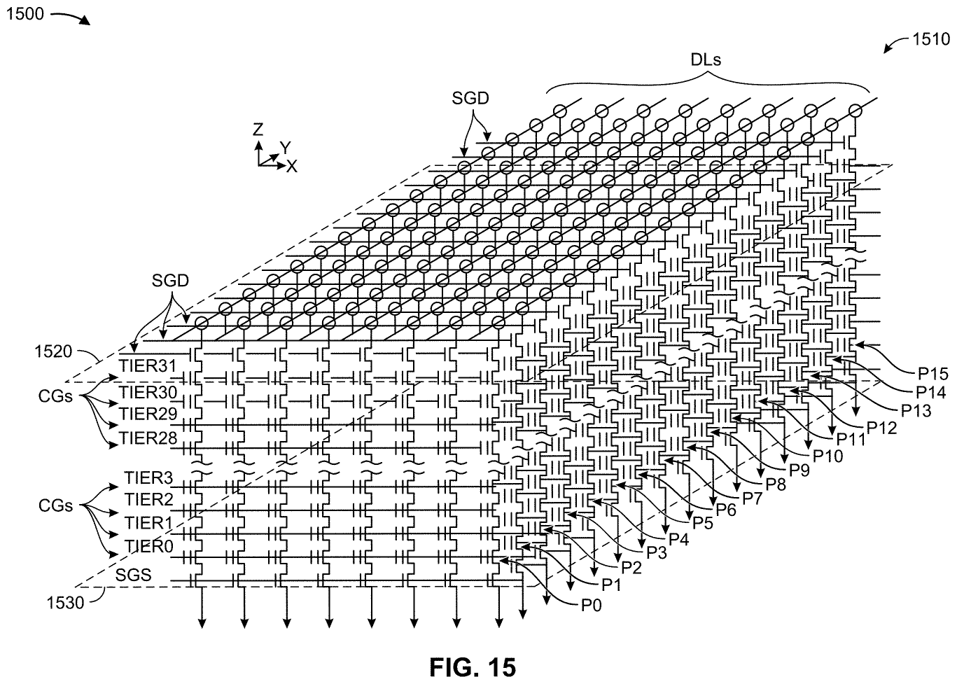

FIG. 15 is a diagram illustrating an example 1500 of a memory array 1510. Although FIG. 15 shows a 3D NAND memory array, some implementations described herein may be performed in connection with another type of memory array, such as a 2D memory array.

The memory array 1510 includes multiple strings of memory cells, and each string including 32 tiers (shown as TIER0-TIER31) of charge storage transistors stacked in the Z direction, source to drain, from a source-side select gate (SGS) to a drain-side select gate (SGD). Each string of memory cells in the memory array 1510 may be arranged along the Y direction as data lines (shown as DLs), and along the X direction as pages (shown as P0-P15). Within a page, each tier represents a row of memory cells, and each string of memory cells represents a column. A block of memory cells may include a number of pages (e.g., 128 or 384). In other examples, each string of memory cells may include a different number of tiers (e.g., 8, 16, 64, or 128), and/or one or more additional tiers of semiconductor material above or below the charge storage transistors (e.g., to form select gates or data lines).

Each memory cell in the memory array 1510 includes a control gate coupled to (e.g., electrically or otherwise operatively connected to) an access line, which collectively couples the control gates across a specific tier or a portion of a tier. Specific tiers in the 3D memory array, and accordingly, specific memory cells in a string, may be accessed or controlled using respective access lines. For example, the memory array 1510 includes a first level of semiconductor material 1520 (e.g., silicon material, such as polysilicon) that couples the control gates of each memory cell in TIER31, and a second level of semiconductor material 1530 that couples the SGS of the array. Similar levels of metal or semiconductor material may couple the control gates for each tier. Specific strings of memory cells in the array may be accessed, selected, or controlled using a combination of data lines (DLs) and select gates, and specific memory cells at one or more tiers in the specific strings may be accessed, selected, or controlled using one or more access lines. In some implementations, the memory device 1310, the memory device 1402, the memory device 140, and/or the device 200 may include the memory array 1510 of FIG. 15. For example, the memory array 1325 and/or the memory array 1404 may be the memory array 1510.

As indicated above, FIG. 15 is provided as an example. Other examples may differ from what is described with regard to FIG. 15.

In some implementations, a memory device includes one or more components configured to: apply a read voltage to multiple access lines of a block of memory; determine, based on applying the read voltage to the multiple access lines, a quantity of access lines for which a corresponding page stores data, wherein each access line provides access to one or more pages of memory; and identify a most recently programmed page of the block of memory based on the determined quantity of access lines.

In some implementations, an apparatus includes means for performing an erase verify read operation to read from a plurality of access lines of a block of memory; means for determining, based on performing the erase verify read operation, a quantity of access lines for which a corresponding page has been programmed, wherein each access line provides access to one or more pages of memory; and means for identifying a most recently programmed page of the block of memory based on the determined quantity of access lines.

In some implementations, a method includes reading marker data from a plurality of memory pages corresponding to a plurality of access lines of a block of memory, wherein the marker data indicates, for a corresponding memory page from which the marker data is read, whether that corresponding memory page has been programmed; determining, based on reading the marker data, a quantity of access lines, of the plurality of access lines, for which a respective memory page has been programmed; identifying a memory page, of the block of memory, from which user data is to be read based on the determined quantity of access lines; and reading the user data from the identified memory page.

In some implementations, a memory device includes one or more components configured to: write user data to a page of memory included in a block of memory, wherein the page is configured to include: a first memory portion configured to store the user data; and a second memory portion configured to store marker data indicative of whether the user data has been written to the first memory portion, wherein the second memory portion is configured to include a separate location for each access line via which the block of memory is accessible; and write, in a location in the second memory portion that is based on the page, an indication that the user data has been written to the first memory portion of the page.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
apply a read voltage to multiple access lines of a block of memory;
determine, based on applying the read voltage to the multiple access lines, a quantity of access lines for which a corresponding page stores data,
wherein each access line provides access to one or more pages of memory; and
identify a most recently programmed page of the block of memory based on the determined quantity of access lines.

2. The memory device of claim 1, wherein each access line of the block of memory is associated with at least one page that is configured to store:
marker data indicative of whether the at least one page has been programmed; and
security data associated with performing one or more security operations for the memory device.

3. The memory device of claim 2, wherein the one or more components, to determine the quantity of access lines for which a corresponding page stores data, are configured to determine the quantity of access lines based on the marker data.

4. The memory device of claim 2, wherein the one or more components, to determine the quantity of access lines for which a corresponding page stores data, are configured to determine the quantity of access lines based on masking the security data.

5. The memory device of claim 2, wherein the one or more components are configured to:
program a page with the security data; and
store an indication that the page has been programmed based on programming the page with the security data,
wherein the one or more components are configured to store the indication in a location in the marker data corresponding to an access line via which the page is accessible.

6. The memory device of claim 1, wherein each access line of the block of memory is associated with multiple pages that are programmed according to an order; and
wherein the one or more components, to identify the most recently programmed page, are configured to:
identify an access line corresponding to the determined quantity of access lines; and
read all pages accessible via the access line to identify the most recently programmed page, wherein the most recently programmed page is a last page that has been programmed according to the order.

7. The memory device of claim 1, wherein the one or more components are configured to:
read security data stored in the most recently programmed page; and
store the security data in volatile memory of the memory device.

8. An apparatus, comprising:
means for performing an erase verify read operation to read from a plurality of access lines of a block of memory;
means for determining, based on performing the erase verify read operation, a quantity of access lines for which a corresponding page has been programmed, wherein each access line provides access to one or more pages of memory; and
means for identifying a most recently programmed page of the block of memory based on the determined quantity of access lines.

9. The apparatus of claim 8, wherein the means for performing the erase verify read operation comprises means for performing an operation associated with verifying that the block of memory has been erased.

10. The apparatus of claim 8, wherein the block of memory is a dedicated security block that is configured to store security data for the apparatus.

11. The apparatus of claim 8, wherein the means for performing the erase verify read operation to read from the plurality of access lines of the block of memory comprises means for performing the erase verify read operation to read from all access lines of the block of memory.

12. The apparatus of claim 8, wherein each access line, of the plurality of access lines, is associated with a respective page that is configured with:
a first memory portion configured to store user data; and
a second memory portion configured to store marker data indicative of whether the respective page has been programmed with the user data.

13. The apparatus of claim 12, further comprising:
means for programming a page with the user data; and
means for storing the marker data, based on programming the page with the user data, in a set of memory locations, of the second memory portion, that corresponds to an access line via which the page is accessible.

14. A method, comprising:
reading marker data from a plurality of memory pages corresponding to a plurality of access lines of a block of memory,
wherein the marker data indicates, for a corresponding memory page from which the marker data is read, whether that corresponding memory page has been programmed;
determining, based on reading the marker data, a quantity of access lines, of the plurality of access lines, for which a respective memory page has been programmed;
identifying a memory page, of the block of memory, from which user data is to be read based on the determined quantity of access lines; and
reading the user data from the identified memory page.

15. The method of claim 14, further comprising:
programming a particular memory page; and
storing a marker data indication based on programming the particular memory page,
wherein the marker data indication indicates that the particular memory page has been programmed, and
wherein the marker data indication is stored in a portion of the particular memory page that corresponds to an access line, of the plurality of access lines, via which the particular memory page is accessible.

16. The method of claim 14, wherein reading the marker data comprises reading the marker data from the plurality of access lines using an erase verify read command.

17. The method of claim 14, wherein the marker data is read as part of an initialization procedure performed by a memory device that includes the block of memory.

18. The method of claim 14, wherein the memory page from which the user data is to be read is a most recently programmed memory page.

19. The method of claim 14, further comprising at least one of:
storing the user data in volatile memory; or
performing one or more security operations based on the user data.

20. A memory device, comprising:
one or more components configured to:
write user data to a page of memory included in a block of memory, wherein the page is configured to include:
a first memory portion configured to store the user data; and
a second memory portion configured to store marker data indicative of whether the user data has been written to the first memory portion,
wherein the second memory portion is configured to include a separate location for each access line via which the block of memory is accessible; and
write, in a location in the second memory portion that is based on the page, an indication that the user data has been written to the first memory portion of the page.

21. The memory device of claim 20, wherein the one or more components are configured to determine that the block of memory is a security block; and
wherein the one or more components, to write the indication that the user data has been written to the first memory portion of the page, are configured to write the indication based on determining that the block of memory is the security block.

22. The memory device of claim 20, wherein the one or more components are configured to:
store data cycling information that identifies a data cycling pattern that indicates correspondences between access lines and locations of the second memory portion; and
determine the location in the second memory portion based on the data cycling pattern.

23. The memory device of claim 22, wherein the one or more components are configured to:
update the data cycling information to identify a different data cycling pattern based on erasing the block of memory.

24. The memory device of claim 20, wherein the one or more components are configured to:
apply a read voltage to every access line included in the block of memory;
determine, based on applying the read voltage, a quantity of access lines for which a corresponding page stores data; and
identify a most recently programmed page of the block of memory based on the determined quantity of access lines.

25. The memory device of claim 20, wherein the location comprises multiple bytes of memory; and
wherein the one or more components are configured to:
read the marker data from the multiple bytes of memory; and
perform error correction to recover the marker data based on reading the marker data from the multiple bytes of memory.
